(19) United States
(12) Patent Application Publication
(10) Pub. No.: US 2026/0348885 A1
(43) Pub. Date: Nov. 5, 2026

(54) METHOD FOR ANALYZING ALKALI ION COMPOSITION IN LIPON THIN FILM, METHOD FOR ANALYZING ALKALI ION COMPOSITION IN ALL-SOLID-STATE BATTERY, AND APPARATUS FOR ANALYZING ALKALI ION COMPOSITION IN LIPON THIN FILM

(71) Applicant: Korea Advanced Institute of Science and Technology, Daejeon (KR)

(72) Inventors: Gyungtae Kim, Daejeon (KR); Tae Gun Kim, Cheongju-si, Chungcheongbuk-do (KR); Yun Chang Park, Daejeon (KR)

(21) Appl. No.: 19/487,450

(22) PCT Filed: May 24, 2024
(86) PCT No.: PCT/KR2024/007099

§ 371 Date: Nov. 24, 2025

(30) Foreign Application Priority Data
Sep. 11, 2023 (KR) 10-2023-0120408

(51) Int. Cl. G01N 23/083

(52) U.S. Cl. CPC G01N 23/083; G01N 2223/61

(57) ABSTRACT

The present disclosure provides a method for analyzing an alkali ion composition in a LiPON thin film and a method for analyzing an alkali ion composition in an all-solid-state battery. The method for analyzing an alkali ion composition in a LiPON thin film comprises: a step of preparing a substrate and a sample including a lithium phosphorus oxynitride (LiPON) thin film disposed on one surface of the substrate; and a step of irradiating monoatomic ion beams to the surface of the lithium phosphorus oxynitride thin film, wherein in the step of irradiating ion beams, a positive voltage is applied to the other surface of the substrate.

### TECHNICAL FIELD

The present disclosure relates to a method for analyzing an alkali ion composition in a LiPON thin film, a method for analyzing an alkali ion composition in an all-solid-state battery, and an apparatus for analyzing an alkali ion composition in a LiPON thin film, and more particularly, to a method and apparatus for analyzing a compositional distribution of alkali ions in a LiPON thin film or an all-solid-state battery using ion beam sputtering.

### BACKGROUND ART

A lithium ion battery is composed of a cathode, an anode, a separator, and an electrolyte. In particular, a battery in which the electrolyte is solid rather than liquid is called an all-solid-state battery. Solid electrolytes may be classified into sulfide-based, oxide-based, and polymer-based types depending on their kinds. Meanwhile, alkali metal ions migrate between the anode and cathode through the solid electrolyte. In this case, accurate analysis and accurate interpretation of the behavior and quantitative distribution of alkali metal ions under varying charge and discharge conditions in the all-solid-state battery are necessary.

In order to determine information according to the chemical state and depth distribution of alkali metals, accurate information may be obtained through time-of-flight secondary ion mass spectrometry (TOF-SIMS) and X-ray photoelectron spectroscopy (XPS), etc. For example, depth profiling using the X-ray photoelectron spectrometer repeats a process of sputtering the surface layer to the desired depth through ion bombardment, which accelerates ions such as Ar⁺, C60⁺, and Arₙ⁺ onto a surface of the sample, and then irradiating X-rays again to analyze photoelectrons. However, during the ion bombardment, positive ions that collide with the sample form an electric field on a surface of a sample to repel or attract conductive ions in the sample, thereby causing the compositional distribution of the sample to change significantly compared to its original state during depth distribution analysis. A representative example is the widely known phenomenon of alkali cations such as Li+, Na+ etc., being pushed out from the surface and piled-up in large quantities at a bottom of the sample when bombarded with cations such as Ar⁺. This phenomenon not only obscures the original compositional distribution of the sample, but also causes chemical reactions in the sample during ion transport, thereby losing the inherent physical and chemical properties of the material originally intended for investigation.

Therefore, various countermeasures have been proposed for depth distribution analysis using ion bombardment to prevent this ion pile-up phenomenon. Examples include changing the types of elements used for ion bombardment, providing additional negative charges to the surface to prevent electric field formation, reducing ion migration by extremely lowering the temperature of the sample, and performing ion bombardment as ion clusters instead of single atomic ions. However, the above-described methods have many limitations in practical use, such as being difficult to use universally in various environments, being able to adversely affect the strength of the observed signal, and taking a lot of time and money to implement.

### DISCLOSURE

### Technical Problem

The present disclosure is intended to solve the above-described conventional problems, and an object of the present disclosure is to provide a technique that can eliminate the pile-up of cations (particularly Li⁺) in the solid electrolyte during compositional analysis of lithium phosphorus oxynitride (LiPON), which is a type of inorganic solid electrolyte, and enable more accurate depth-profiling. However, the problems are merely examples and are not intended to limit the scope of the present disclosure.

### Technical Solution

According to one aspect of the present disclosure, there is provided a method for analyzing an alkali ion composition in a LiPON thin film.

The method for analyzing an alkali ion composition in a lithium phosphorus oxynitride (LiPON) thin film includes: preparing a sample including a substrate and a LiPON thin film disposed on one surface of the substrate; and irradiating monoatomic ion beams to a surface of the LiPON thin film, in which, in the irradiating of the ion beams, a positive voltage is applied to the other surface of the substrate.

The irradiating of the ion beams may include supplying a gas selected from the group consisting of hydrogen (H₂), nitrogen (N₂), argon (Ar), neon (Ne), krypton (Kr), and xenon (Xe) for generating the monoatomic ion beam.

The irradiating of the ion beams may include accelerating the monoatomic ion beam with an acceleration voltage of 0.5 keV to 4 keV.

According to another aspect of the present disclosure, there is provided a method for analyzing an alkali ion composition in a LiPON thin film.

The method for analyzing an alkali ion composition in an all-solid-state battery includes: preparing the all-solid-state battery including an electrode layer; and a solid electrolyte layer comprising a lithium phosphorus oxynitride (LiPON) thin film disposed on one surface of the electrode layer; and irradiating monoatomic ion beams to a surface of the solid electrolyte layer, in which, in the irradiating of the ion beams, a positive voltage is applied to the other surface of the electrode layer.

The applied positive voltage may be greater than or equal to an operating voltage of the all-solid-state battery.

The all-solid-state battery may be a lithium secondary battery, and the applied positive voltage may be greater than or equal to 3.7 V.

The all-solid-state battery may be a sodium secondary battery, and the applied positive voltage may be greater than or equal to 2.3 V.

The applied positive voltage may be greater than or equal to a critical potential at which lithium ion pile-up (Li pile-up) occurs.

In the irradiating of the ion beams, when the ion gun energy is 2000 eV, the applied positive voltage may be greater than or equal to 7 V.

According to another aspect of the present disclosure, there is provided an apparatus for analyzing an alkali ion composition in a LiPON thin film.

The apparatus for analyzing an alkali ion composition in a LiPON thin film for analyzing a sample including a substrate and a LiPON thin film disposed on one surface of the substrate includes: an ion beam generation unit equipped to supply gas for generating monoatomic ion beams; and a power control unit configured to control a positive voltage to be applied to the other surface of the substrate when the monoatomic ion beams generated by the ion beam generation unit are irradiated to a surface of the thin film.

The apparatus may be an X-ray photoelectron spectrometer (XPS).

The apparatus may further include a flood gun configured to supply electrons to a surface of the sample.

### Advantageous Effects

As described above, according to the embodiments of the present disclosure, the accurate spatial distribution and quantitative distribution analysis of alkali metal ions are possible, thereby preventing errors in characteristic analysis of lithium all-solid-state batteries and contributing to performance enhancement. In addition, the present disclosure has the advantage of being less dependent on experimental environments and easier to apply than existing ion pile-up prevention techniques.

Of course, the scope of the present disclosure is not limited to the above-described effects.

### BRIEF DESCRIPTION OF THE DRAWINGS

FIG. 1 is a schematic diagram of (a) conventional ion beam sputtering and (b) ion beam sputtering according to an embodiment of the present disclosure.

FIG. 2 is a depth distribution analysis spectrum of alkali metal (Li) in an all-solid-state battery according to an embodiment of the present disclosure.

FIG. 3 is a depth distribution analysis graph of alkali metal (Li) in an all-solid-state battery according to an embodiment of the present disclosure.

FIG. 4 is a schematic diagram illustrating an apparatus for analyzing an alkali ion composition in a LiPON thin film according to an embodiment of the present disclosure.

FIGS. 5 and 6 are graphs illustrating the migration of alkali ions (Li) in a LiPON thin film according to conventional ion beam sputtering.

FIG. 7 is a graph illustrating the migration of alkali ions in a LiPON thin film according to an embodiment of the present disclosure.

FIG. 8 is an XPS spectrum analysis result in a LiPO sample according to the applied bias voltage in an embodiment of the present disclosure.

FIG. 9 is an XPS spectrum analysis result at a LiPO/Si interface according to an applied bias voltage in an embodiment of the present disclosure.

FIG. 10 is a graph illustrating a Si atomic concentration as a magnitude of the applied bias voltage during ion beam sputtering according to an embodiment of the present disclosure.

### EMBODIMENTS

Hereinafter, various embodiments of the present disclosure will be described in detail with reference to the accompanying drawings. Embodiments of the present disclosure will be provided only in order to further completely describe the present disclosure to those skilled in the art, the following embodiments may be modified into several other forms, and the scope of the present disclosure is not limited to the following embodiments. Rather, these embodiments make the present disclosure thorough and complete, and are provided in order to completely transfer the spirit of the present disclosure to those skilled in the art. In addition, thicknesses or sizes of the respective layers in the drawings have been exaggerated for convenience and clarity of explanation.

Hereinafter, a method for analyzing an alkali ion composition in a LiPON thin film, a method for analyzing an alkali ion composition in an all-solid-state battery, and an apparatus for analyzing an alkali ion composition in a LiPON thin film according to embodiments of the present disclosure will be described.

Lithium phosphorus oxynitride (LiPON), a kind of inorganic solid electrolyte, has the advantages of stable contact with lithium metal, a wide potential range (0 to 5.5 V vs. Li/Li+), and negligibly low electrical conductivity. Therefore, the LiPON has been widely used as a reference electrolyte in the research and development of thin-film all-solid-state lithium batteries. However, the LiPON may be used only in the form of a thin-film electrolyte due to its low ionic conductivity (~10⁻⁶ Scm⁻¹ at 25 °C).

In the case of an all-solid-state battery containing a lithium phosphate oxynitride (LiPON) thin film as an electrolyte, alkali metals migrate in the all-solid-state material during charge and discharge. However, this migration should not occur during measurements and analysis to analyze the depth-wise composition of the all-solid-state battery. When the alkali metals migrate, their compositions may change at the interface between the cathode and the solid electrolyte, the interface between the anode and the solid electrolyte, and in the all-solid-state material, potentially resulting in deterioration of battery performance.

Therefore, the present disclosure provides an analytical method for accurately analyzing and correctly interpreting the composition of alkali metals in an all-solid-state battery.

According to an embodiment of the present disclosure, a method for analyzing an alkali ion composition in a LiPON thin film includes: preparing a sample including a substrate and a lithium phosphate oxynitride (LiPON) thin film disposed on one surface of the substrate; and irradiating monoatomic ion beams to a surface of the lithium phosphorus oxynitride (LiPON) thin film, in which, in the irradiating of the ion beams, a positive voltage is applied to the other surface of the substrate.

First, the sample including the substrate and the LiPON thin film disposed on one surface of the substrate is prepared.

The substrate may be glass, silicon, plastic, or other dielectric substrate. The method for depositing a lithium phosphorus oxynitride thin film on the substrate is not particularly limited. For example, the LiPON thin film may be deposited on the substrate by high-frequency sputtering using a Li₃PO₄ target in a nitrogen atmosphere. It is also possible to use a lithium phosphate (LiPO) sample in a nitrogen-free form by exposing the sample thus prepared to air at room temperature.

Next, the monoatomic ion beams are irradiated to the surface of the lithium phosphorus oxynitride (LiPON) thin film.

As a gas for generating the monoatomic ion beams, hydrogen (H₂), nitrogen (N₂), oxygen (O₂), argon (Ar), neon (Ne), krypton (Kr), or xenon (Xe) gas may be supplied. The supplied gas may be ionized into monoatomic ions such as H⁺, N₂⁺, O⁺, Ar⁺, Kr⁺, and Xe⁺. The ionized monoatomic ions are accelerated and collided with the surface of the LiPON thin film of the sample.

When the monoatomic ion beams are irradiated on the sample, energy is transferred to atoms in the LiPON thin film, so that the mobility of alkali ions such as lithium may increase.

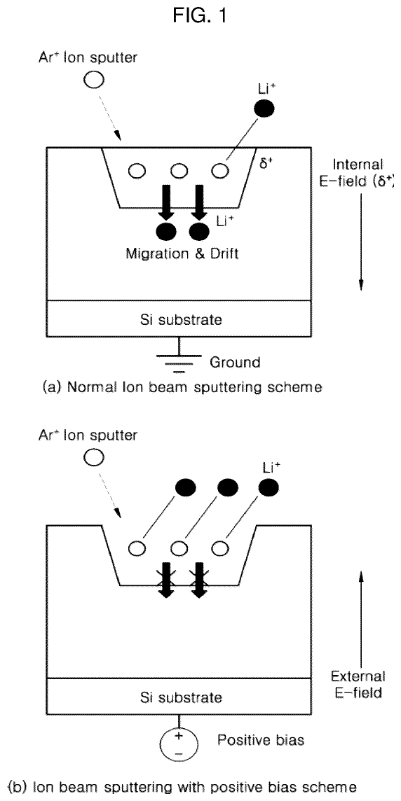

FIG. 1 is a schematic diagram of (a) conventional ion beam sputtering and (b) ion beam sputtering according to an embodiment of the present disclosure.

(a) of FIG. 1 is a schematic diagram illustrating the generation of an electric field on the surface during Ar⁺ monoatomic ion beam sputtering on a solid electrolyte sample, the resulting migration of Lit cations, and the resulting ion pile-up phenomenon.

When Ar⁺ ions collide with the surface of the sample, lithium (Li) on the surface of the sample and in the corresponding region becomes positively charged. The lithium cations (Li⁺) try to migrate away from the positively charged (δ⁺) surface and migrate (drift) to a bottom of the sample, where there is relatively less positive charge, through ion conduction. However, when the lithium cations (Li⁺) encounter the region (here, Si substrate) where the ion conduction is not smooth, the lithium cations are unable to migrate further and pile-up in the corresponding region. In other words, during the ion bombardment, the upper portion (surface) of the sample gradually becomes depleted of lithium, while the lower portion (i.e., inner portion, near the substrate) shows an excessive distribution of lithium compared to the original composition.

(b) of FIG. 1 illustrates an example of resolving this ion pile-up phenomenon. Applying a positive bias greater than or equal to a surface potential converged at the bottom of the sample may prevent the migration of lithium cations. Here, the potential was applied to the bottom of the sample by applying the positive bias to the Si substrate. A positive potential applied to the bottom of the sample also repels lithium cations, similar to the surface potential. Consequently, the migration of the lithium cations downward is inhibited as the bottom potential increases. When the bottom potential exceeds the surface potential, lithium cations no longer migrate downward and remain on the surface. This prevents the abnormal behavior of the lithium cations and enables the accurate compositional analysis.

According to another embodiment of the present disclosure, a method for analyzing an alkali ion composition in an all-solid-state battery is provided.

The method for analyzing an alkali ion composition in an all-solid-state battery includes preparing the all-solid-state battery including an electrode layer and a solid electrolyte layer including a lithium phosphorus oxynitride (LiPON) thin film disposed on one surface of the electrode layer; and irradiating monoatomic ion beams to a surface of the solid electrolyte layer, in which, in the irradiating of the ion beams, a positive voltage is applied to the other surface of the electrode layer.

First, the all-solid-state battery including the solid electrolyte layer including the lithium phosphorus oxynitride (LiPON) thin film is prepared. The solid electrolyte layer is interposed between the cathode and anode layers and serves as a conductor responsible for the migration of alkali ions during the charging and discharging of the all-solid-state battery.

The electrode layer includes a cathode, which generates lithium ions through a chemical reaction during the charging of the all-solid-state battery. The electrode layer may include a cathode active material that is a metal oxide, and may preferably further include a conductive material, a binder, and a solid electrolyte.

The electrode layer includes an anode, which may comprise a metal-based anode active material and may be manufactured by press-molding onto a current collector.

Next, the monoatomic ion beams are irradiated to the surface of the solid electrolyte layer.

In the irradiating of the ion beams, the positive voltage is applied to the other surface of the electrode layer where the solid electrolyte layer is not formed.

Here, the applied positive voltage may be higher than the operating voltage of the all-solid-state battery. When the applied positive voltage does not reach the operating voltage of the battery, the effect of 41 offsetting the migration of lithium cations during the measurement of the lithium cations by the external electric field may not be expected.

For example, the all-solid-state battery may be a lithium secondary battery. In this case, the applied positive voltage is preferably 3.7 V or higher. As another example, the all-solid-state battery may be a sodium secondary battery. In this case, the applied positive voltage is preferably 2.3 V or higher. However, this is merely an example case, and the present disclosure is not limited thereto, and any voltage higher than or equal to the operating voltage of the all-solid-state battery may be used.

In embodiments of the present disclosure, since the lithium ion pile-up phenomenon requires the mobilization of Li by ion bombardment, it is preferable to apply a positive voltage greater than or equal to a breakdown potential that is a critical potential that triggers the pile-up of lithium cations. As long as the positive voltage applied to the substrate is greater than or equal to the breakdown potential, the degree to which the lithium ions pile up in the all-solid-state battery may decrease. Therefore, it is preferable to apply a positive voltage near the breakdown potential.

However, the critical substrate potential for resolving the ion pile-up phenomenon may vary depending on the sample properties and experimental conditions related to the ion bombardment. Therefore, it is preferable to apply the positive voltage corresponding to the breakdown potential after confirming the degree to which ions pile up under each experimental condition.

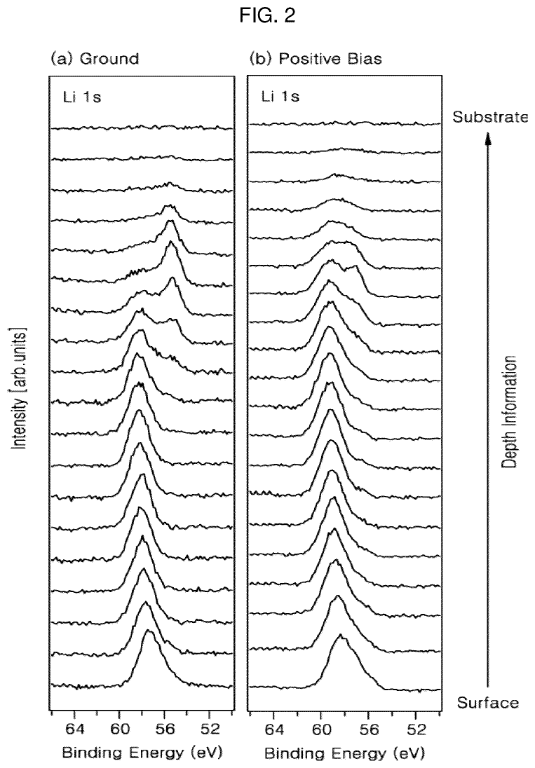

FIG. 2 illustrates a depth distribution analysis spectrum of alkali metal (Li) in an all-solid-state battery, depending on whether a bias is applied or not.

(a) of FIG. 2 illustrates a Li 1s core-level spectrum when no bias is applied (ground), and (b) of FIG. 2 illustrates a Li 1s core-level spectrum when a positive voltage is applied (positive bias). Referring to these figures, in the case of the ion beam sputtering according to (a) of FIG. 2, it may be confirmed that Li has a metallic form as it migrates from the surface toward the substrate during the sputtering. That is, when the positive voltage is not applied, alkali ions may migrate toward the interface between the electrode layer and the solid electrolyte layer and pile-up. When the positive voltage is applied to the same specimen according to (b) of FIG. 2, it may be seen that cations are distributed more extensively than metals in the depth direction.

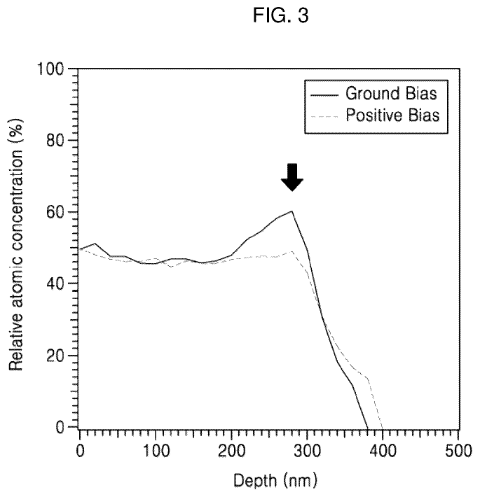

FIG. 3 is a depth distribution analysis graph of alkali metal (Li) in an all-solid-state battery according to an embodiment of the present disclosure.

Referring to FIG. 3, a graph is illustrated that converts the Li quantification into a depth distribution profile based on the Li 1s spectrum obtained through an X-ray spectrometer. When no bias is applied (ground bias), the form in which the alkali metal appears to be accumulated at the interface (black arrow) is shown. However, when the positive voltage (positive bias) is applied, it may be seen that the phenomenon at the interface disappears. In this case, the relative sensitivity factors used were A (1.0) and B (X.x), respectively.

Meanwhile, the LiPON may undergo an interface reaction with the electrode layer through X-ray photoelectron emission, but this reaction is limited and therefore may be ignored.

According to another embodiment of the present disclosure, an apparatus for analyzing an alkali ion composition in a LiPON thin film is provided.

The apparatus for analyzing an alkali ion composition in a LiPON thin film is an apparatus for analyzing a sample including a substrate and a lithium phosphate oxynitride (LiPON) thin film disposed on one surface of the substrate, and may be an X-ray photoelectron spectrometer (XPS).

The apparatus may include an ion beam generation unit equipped to supply gas for generating monoatomic ion beams; and a power control unit configured to control a positive voltage to be applied to the other surface of the substrate when the monoatomic ion beams generated by the ion beam generation unit are irradiated to a surface of the thin film. The apparatus may further include a flood gun supplying electrons to a surface of the sample.

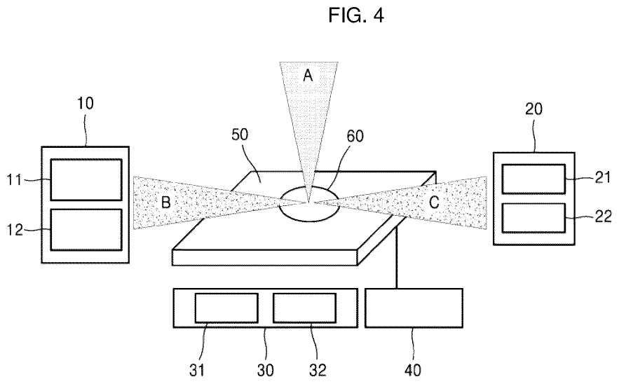

FIG. 4 is a schematic diagram of an X-ray photoelectron spectrometer (XPS) device, which is the apparatus for analyzing an alkali ion composition in a LiPON thin film according to an embodiment of the present disclosure.

Referring to FIG. 4, a sample S is seated on a sample holder H, and the apparatus is configured to include an X-ray source A that irradiates X-rays to the sample S, an ion beam generation unit B that irradiates ion beams, a flood gun C that supplies electrons, and a power control unit 40 that controls the positive voltage to be applied to the other surface of the sample when the monoatomic ion beams generated from the ion beam generation unit B are irradiated to one surface of the sample S.

The ion beam generation unit B is configured to include a monoatomic ion beam injection unit 11 and a gas cluster ion beam injection unit 12, and has a structure capable of injecting monoatomic ions and gas cluster ions, respectively. The flood gun C is a device that functions to neutralize the surface of the sample, and includes a first mode 21 that controls the energy and area of applied electrons, which is set under conditions of a general grounded state. Therefore, a separate mode suitable for the condition in which the positive bias is applied is required, and is used by being set to the second mode 22 that is optimized for a specific amount of power.

Furthermore, for the quantitative analysis of the components of the all-solid-state battery, a relative sensitivity factor (RSF) is used. In addition to a fixed first RSF 31, a second RSF 32 may be provided, when positive power rather than a ground power is applied to the surface of the sample, the potential of the surface changes, and the apparatus may be provided with a second RSF 32 optimized for conditions in which the ionization rate of electrons due to X-rays varies.

Hereinafter, the present disclosure will be described in more detail with through examples. However, these examples are provided for illustrative purposes and are not intended to limit the scope of the present disclosure.

### EXAMPLE

As a comparative example, monoatomic ion beams of Ar⁺ and Net are irradiated to a surface of a lithium phosphorus oxynitride (LiPON) thin film disposed on a substrate using an X-ray photoelectron spectrometer.

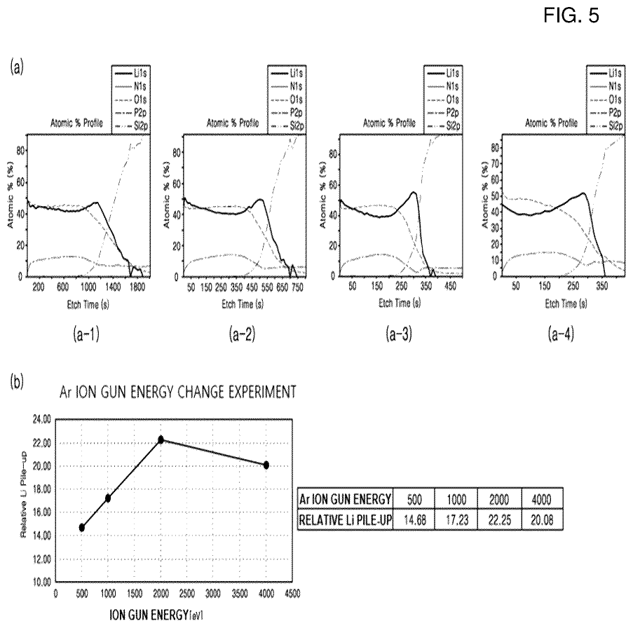

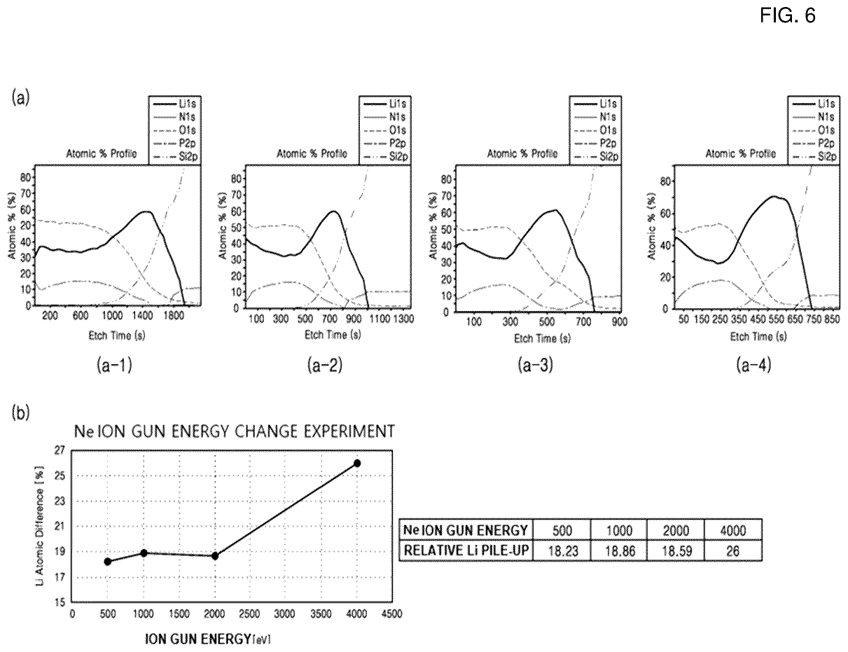

FIGS. 5 and 6 are graphs illustrating the migration of alkali ions (Li) in a LiPON thin film when various ion gun energies are irradiated using Ar and Ne gases according to conventional monoatomic ion beam sputtering.

(a) of FIG. 5 showed an experiment result in which the Ar⁺ monoatomic ion gun energy varied to (a-1) 500 eV, (a-2) 1000 eV, (a-3) 2000 eV, and (a-4) 4000 eV. The Li pile-up phenomenon occurred across all energy bands. While the Li pile-up phenomenon increased as the ion gun energy increases, it was not linearly proportional.

(b) of FIG. 5 is a graphical representation of the amount of Li pile-up at the interface as the ion gun energy varies. An X-axis represents the ion gun energy, and a Y-axis represents the result of subtracting the average Li composition in the LiPON thin film from the Li content at the interface. As a result, it may be confirmed that the pile-up phenomenon occurs at all the ion gun energies.

FIG. 6 is a graph showing the migration of alkali ions (Li) in the LiPON thin film when various ion gun energies are irradiated using the Ne gas.

Referring to FIG. 6, the results of the experiment to improve the Li pile-up phenomenon using Ne, which has a lower atomic number than Ar, were shown.

(a) of FIG. 6 showed the results of an experiment in which the Net monoatomic ion gun energies varied to (a-1) 500 eV, (a-2) 1000 eV, (a-3) 2000 eV, and (a-4) 4000 eV. It was confirmed that the Li pile-up phenomenon occurred in all the methods using the Ne gas.

(b) of FIG. 6 showed the relative degree of Li pile-up as the Ne ion gun energy changes. This demonstrates that conventional monoatomic ion beam sputtering induces lithium mobility, leading to the Li pile-up at the interface.

As an example, the Ar⁺ monoatomic ion beams were irradiated to the surface of the lithium phosphate oxynitride (LiPON) thin film positioned on a substrate at 2000 eV ion gun energy using the X-ray photoelectron spectrometer. In this case, the positive voltage was applied to the lower portion of the substrate.

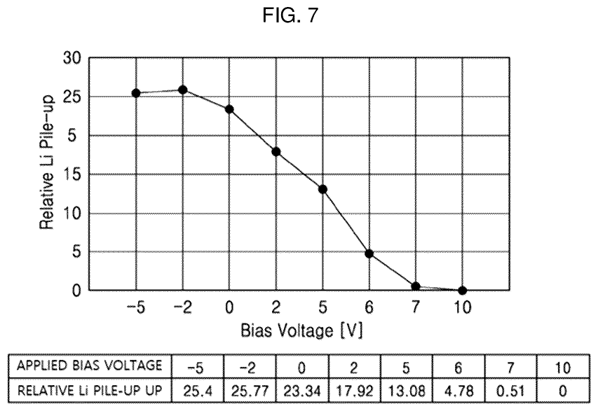

FIG. 7 is a graph showing the migration of alkali ions in the LiPON thin film depending on the applied bias voltage.

Referring to FIG. 7, it may be confirmed that Li pile-up phenomenon generally decreases as the applied bias voltage increases. In particular, the lithium pile-up phenomenon hardly occurred at voltages higher than or equal to +7 V. This is presumably due to a decrease in the mobility of lithium cations in the LiPON thin film caused by the applied bias.

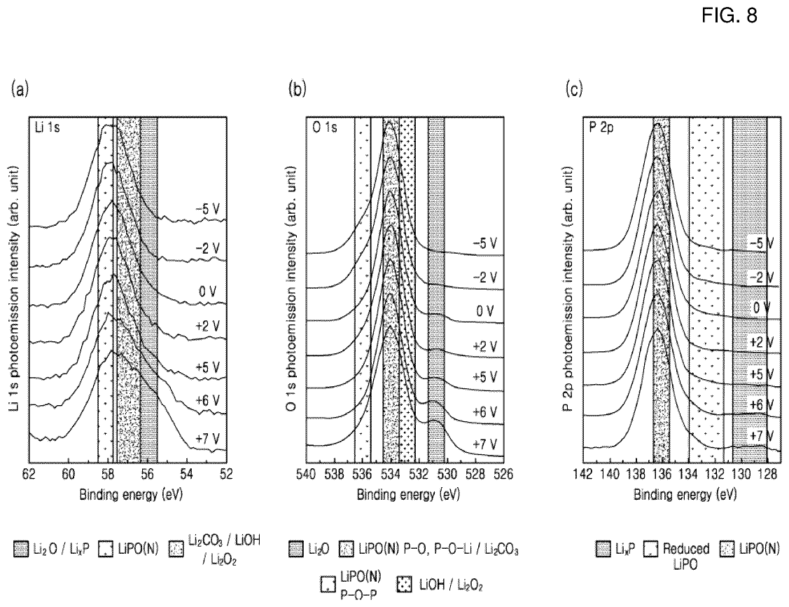

FIG. 8 shows the results of an analysis of the Li 1s, O 1 s , and P 2p core level spectra in a LiPO sample (etching time: 150 s) depending on the applied bias voltage.

What may be seen in FIG. 8 is that as the substrate potential increases in the positive direction, the portion corresponding to Li2O, which is the lower binding energy side of the Li 1s and O 1s peaks, increases. In particular, this change is particularly noticeable when a potential greater than or equal to the critical potential for ion pile-up resolution is applied. Another fact is that as the substrate potential increases, a portion corresponding to the higher binding energy side (shoulder) of the O 1 s peak and a P-O-P bond, which is a binding of P-centered atom of lithium phosphate, tends to decrease. In addition, when the potential greater than or equal to the critical potential is applied, it may be seen through the change in the lower binding energy side of the P 2p peak that some reduced P compounds and lithium phosphide (LixP) are formed from LiPO.

In summary, first, when the substrate potential is small or in the negative direction (when Li pile-up occurs smoothly), the surface Li that has lost its chemical bond due to ion etching quickly migrates down the sample and leaves the surface. However, as the substrate potential increases, the pile-up phenomenon weakens, and the Li that may not migrate downward remains on the surface and easily forms new reactants. This situation may be understood as the formation of an interface between mobile Li and LiPO generated by ion etching. At the same time, the corresponding result also suggests that when the Li pile-up occurs, the Li generated by ion etching quickly migrates downward without much reaction from the surface, and that the application of the positive substrate potential inhibits the migration of Li to promote the retention and reaction of Li on the surface.

Next, the chemical changes at the area where actual Li pile-up occurs and at the interface between the LiPO and Si substrate were examined.

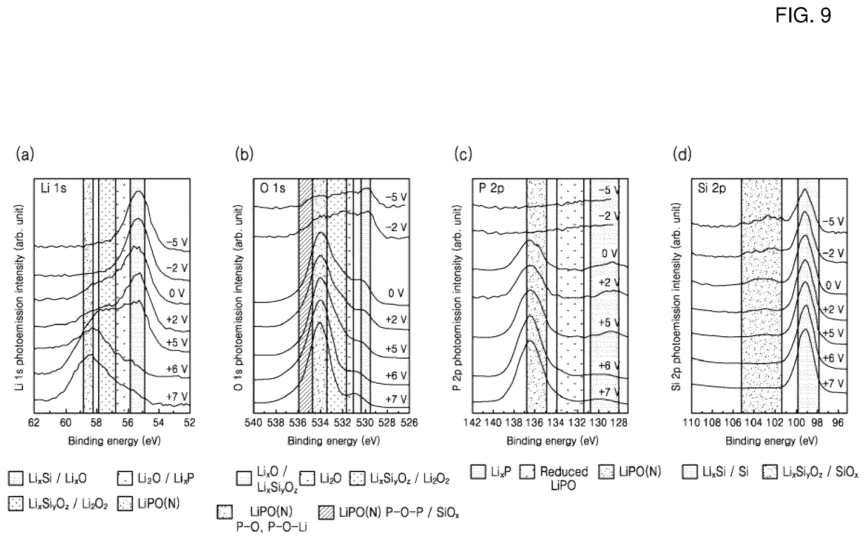

FIG. 9 shows that the Li 1 s, O 1 s, P 2p, and Si 2p XPS spectra at the LiPO/Si interface (etching time 300 s) are arranged according to the applied substrate potential.

From FIG. 9, it may first be observed that when a potential smaller than the threshold potential is applied, a component that is considerably narrow (with a small FWHM) and clearly distinguishable from other chemical states is captured on the lowest binding energy side of the Li Is peak. This peak appears to correspond to lithium silicide (LixSi), which is close to a metallic state. The presence of this peak provides direct evidence for the presence, migration, and pile up of mobile Li in the depth distribution analysis accompanying the ion etching. The proportion of this silicide peak decreases as the substrate potential increases, and when the substrate potential exceeds a critical value, the silicide peak becomes less prominent.

Secondly, the fact that may be known from the Li 1 s and O 1 s peaks is that components corresponding to Li₂ O and lithium silicate (LiₓSi_{γ}O_z) are formed at the interface. Additionally, at the O 1 s peak, components presumed to be lithium-rich oxides (Li-rich oxides, Lixo) or specific lithium silicates (Li silicate, phyllo/ino-silicate) with relatively low binding energy are also identified.

Next, from the P 2p peak, it may be seen that lithium phosphide and reduced phosphorus compounds are also generated at the LiPO/Si interface. At the region above the interface (etching time 200 to 250 s), the formation of lithium phosphide (not illustrated here) is observed relative to the relatively strong bulk LiPO. Therefore, it is estimated that the stronger the Li pile-up, the more lithium phosphide is formed overall. Furthermore, when the substrate potential is large, particularly when a potential greater than or equal to the threshold potential is applied, the formation of the lithium phosphide decreases, whereas the formation of reduced phosphorus compounds increases. Therefore, applying the substrate potential greater than or equal to the critical potential also serves the additional function of suppressing the reaction with Li at the bottom of the sample, thereby maintaining the chemical state of the sample closer to its native LiPO state.

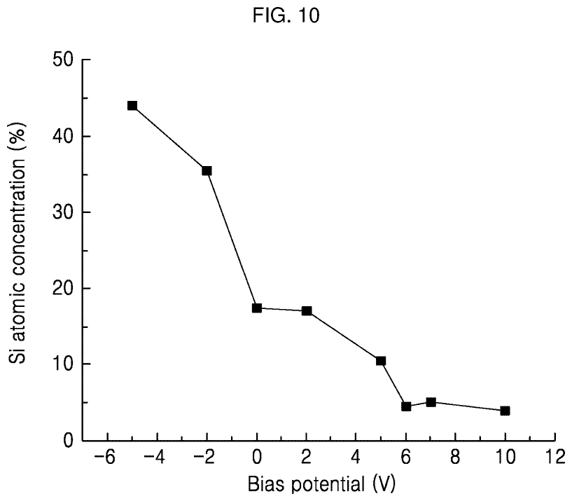

Finally, the Si 2p peak indicates that the higher the substrate potential, the less Si is exposed for the same etching time. This is also evident in FIG. 10. FIG. 10 shows the result of listing the Si atomic concentration observed at an etching time of 300 s during Ar⁺ ion etching with a kinetic energy of 2 keV, according to the magnitude of the bottom voltage. It is clear that the Si composition ratio decreases as the substrate potential increases. This implies that the etching rate of the LiPO sample decreases as the substrate potential increases. This is thought to be because the stronger the Li pile-up, the more LiPO decomposes at the interface, weakening the structure and resulting in faster erosion of the sample.

These results suggest the following conclusions. Mobile Li, which migrates downward due to the Li pile-up, also reacts with LiPO at the LiPO/Si interface. The reaction between the Li and LiPO decomposes LiPO, producing lithium oxide, lithium phosphide, and reduced lithium phosphate. Furthermore, when there is sufficient mobile Li, in addition to the decomposition of LiPO, it reacts with the Si substrate to form interphases such as lithium silicide and lithium silicate. This decomposition reaction is more active as the amount of Li piling up at the bottom increases, i.e., the degree of Li pile-up increases. The reactions in the sample described above occurred without the Li pile-up, so at the LiPO/Si interface, where a large amount of Li is accumulated, more intense reactions occur than inside the bulk of the sample. Furthermore, only causes the decomposition of the LiPO to change its chemical composition, but also reduces the rigidity of the LiPO sample during the decomposition process, thereby increasing the ion etching rate. Therefore, it is clear that the Li pile-up phenomenon causes multi-faceted degradation of solid electrolyte samples such as LiPO and LiPON. It was confirmed that, in order to obtain more accurate and intrinsic physical and chemical information on the solid electrolyte through depth distribution analysis accompanied by ion etching, it is essential to overcome Li pile-up by applying the substrate potential application method according to the embodiment of the present disclosure.

As described above, according to the embodiments of the present disclosure, by simultaneously applying a positive voltage to the bottom of the all-solid-state battery while using the monoatomic ion beams, it is possible to prevent the ion migration and non-ideal behavior. This may significantly shorten the time required for the depth-wise compositional analysis of the all-solid-state battery and contribute to the improved performance of the all-solid-state battery through the accurate depth-wise quantitative analysis.

Furthermore, the analytical method according to the embodiments of the present disclosure is not limited to solid electrolytes containing Li, such as LiPON and LiPO, but may be universally applied to address the ion pile-up phenomenon that may occur during the depth-wise distribution analysis of various solid electrolytes (particularly those containing alkali ions) and ion-conductive materials. Therefore, it is expected to significantly contribute to more accurate compositional analysis of energy/battery-related materials.

Although the present disclosure has been described with reference to embodiments illustrated in the accompanying drawings, it is only an example. It will be understood by those skilled in the art that various modifications and equivalent other example embodiments are possible from the present disclosure. Accordingly, the actual technical protection scope of the present disclosure is to be defined by the following claims.

1. A method for analyzing an alkali ion composition in a lithium phosphorus oxynitride (LiPON) thin film, comprising:
preparing a sample including a substrate and a LiPON thin film disposed on one surface of the substrate; and
irradiating monoatomic ion beams to a surface of the LiPON thin film,
wherein in the irradiating of the ion beams, a positive voltage is applied to the other surface of the substrate.

2. The method of claim 1, wherein the irradiating of the ion beams includes supplying a gas selected from the group consisting of hydrogen (H₂), nitrogen (N₂), argon (Ar), neon (Ne), krypton (Kr), and xenon (Xe) for generating the monoatomic ion beam.

3. The method of claim 1, wherein the irradiating of the ion beams includes accelerating the monoatomic ion beam with an acceleration voltage of 0.5 keV to 4 keV.

4. A method for analyzing an alkali ion composition in an all-solid-state battery, comprising:
preparing the all-solid-state battery including an electrode layer and a solid electrolyte layer including a lithium phosphorus oxynitride (LiPON) thin film disposed on one surface of the electrode layer; and
irradiating a monoatomic ion beam to a surface of the solid electrolyte layer,
wherein, in the irradiating of the ion beams, a positive voltage is applied to the other surface of the electrode layer.

5. The method of claim 4, wherein the applied positive voltage is greater than or equal to an operating voltage of the all-solid-state battery.

6. The method of claim 4, wherein the all-solid-state battery is a lithium secondary battery, and
the applied positive voltage is greater than or equal to 3.7 V.

7. The method of claim 4, wherein the all-solid-state battery is a sodium secondary battery, and
the applied positive voltage is greater than or equal to 2.3 V.

8. The method of claim 4, wherein the applied positive voltage is greater than or equal to a critical potential at which lithium ion pile-up (Li pile-up) occurs.

9. The method of claim 8, wherein in the irradiating of the ion beams, when the ion gun energy is 2000 ev, the applied positive voltage is greater than or equal to 7 V.

10. An apparatus for analyzing an alkali ion composition in a lithium phosphorus oxynitride (LiPON) thin film for analyzing a sample including a substrate and a LiPON thin film disposed on one surface of the substrate, the apparatus comprising;
an ion beam generation unit equipped to supply gas for generating monoatomic ion beams; and
a power control unit configured to control a positive voltage to be applied to the other surface of the substrate when the monoatomic ion beams generated by the ion beam generation unit are irradiated to a surface of the thin film.

11. The apparatus of claim 10, wherein the apparatus is an X-ray photoelectron spectrometer (XPS).

12. The apparatus of claim 11, further comprising:
a flood gun configured to supply electrons to a surface of the sample.
